(19) United States
(12) Patent Application Publication
(10) Pub. No.: US 2008/0254230 A1
(43) Pub. Date: Oct. 16, 2008

(54) PARTICLE DEPOSITION APPARATUS AND PARTICLE DEPOSITION METHOD

(75) Inventors: Isao MATSUI, Iruma-Shi (JP); Tazumi Nagasawa, Yokohama-Shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/842,530

(22) Filed: Aug. 21, 2007

(30) Foreign Application Priority Data
Aug. 23, 2006 (JP) 2006-226734

(51) Int. Cl. C23C 16/452; C23C 16/02

(52) U.S. Cl. 427/532; 118/723 R; 427/569

(57) ABSTRACT

An apparatus and method for depositing particles having uniform diameters onto a substrate are provided. In the particle deposition apparatus, starting materials in a starting gas are reacted with each other to produce particles which are then deposited onto a substrate. The particle deposition apparatus comprises: a reaction vessel comprising a reaction chamber and a back chamber in its interior, a starting gas supply port in communication with the reaction chamber, an exhaust port in communication with the back chamber, and a holder which is disposed within the back chamber and can hold the substrate; a plasma generator for producing plasma within the reaction chamber; and gas flow control unit configured to discharge a post-reaction gas through the exhaust port while producing the plasma. In the particle deposition apparatus, the introduced starting gas is allowed to react to produce and grow particles, and only particles having desired diameters are selected by taking advantage of balance between plasma-derived Coulomb force and gas flow-derived drag and are deposited onto a substrate.

### CROSS REFERENCE TO RELATED APPLICATIONS

This application is based upon and claims the benefit of priority from the prior Japanese Patent Applications No. 226734/2006, filed on Aug. 23, 2006; the entire contents of which are incorporated herein by reference.

### BACKGROUND OF THE INVENTION

1. Field of Invention

This invention provides a particle deposition apparatus and a particle deposition method.

2. Background Art

Nanometer size particles have a large specific surface area (surface area per unit volume) and features, not possessed by conventional fine particles, such as quantum size effect. Accordingly, nanometer size particles have recently become drawn attention as a novel form of materials, and studies have been made on the application of the nanometer size particles, for example, to recording media, battery electrodes, visible light LED elements, and fluorescent substances in displays.

The nanometer size particles may be produced, for example, by a gas phase method using plasma. For example, E. Bertran et al. disclose a method for producing SiC particles as shown in the following reaction formula:

SiH₄+CH₄→SiC+4H₂.

Specifically, the method comprises providing a starting gas comprising monosilane and methane and reacting the starting materials with each other by utilizing plasma to produce SiC particles (see Journal of Vacuum Science & Technology A, USA, March/April, 1996, Vol. 14, No. 2, p. 567).

The particles produced by this method, however, are large in variation of particle diameter. Regarding the nanometer size particles, the particle diameters should be rendered uniform to utilize the above features.

To this end, the above method successively carries out the following steps for particle deposited layer formation. Specifically, at the outset, while producing particles utilizing plasma, particles discharged together with an exhaust gas from the reaction vessel are collected. Next, the collected particles are classified to collect particles having a predetermined uniform particle diameter. The classified particles having a predetermined uniform particle diameter are dispersed in a liquid, and the dispersion liquid is coated onto a substrate. Thus, the prior art technique requires the provision of a number of steps for the formation of a particle deposited layer formed of particles having a uniform particle diameter.

### BRIEF SUMMARY OF THE INVENTION

An object of the present invention is to provide a particle deposition apparatus and a particle deposition method that can form a particle deposited layer formed of particles having a uniform particle diameter in a relatively small number of steps.

According to the present invention, there is provided

a particle deposition apparatus for reacting starting materials in a starting gas with each other to produce particles which are then deposited onto a substrate, said apparatus comprising:

a reaction vessel comprising a reaction chamber and a back chamber in its interior, a starting gas supply port in communication with said reaction chamber, an exhaust port in communication with said back chamber, and a holder which is disposed within said back chamber and can hold said substrate;

a plasma generator for producing plasma within said reaction chamber; and

gas flow control unit configured to discharge a post-reaction gas through said exhaust port while producing said plasma.

According to another aspect of the present invention, there is provided

a particle deposition method for reacting starting materials in a starting gas with each other to produce particles which are then deposited onto a substrate, said method comprising the steps of:

(1) generating plasma while supplying said starting gas into a reaction chamber capable of generating plasma, whereby particles are produced and are grown within said reaction chamber and particles having a diameter falling within a predetermined range are allowed to stay within said reaction chamber;

(2) discharging a post-reaction gas and particles larger than the upper limit of a predetermined particle diameter range, separated within said reaction chamber, from said reaction chamber; and

(3) allowing said plasma to disappear to deposit particles falling within a predetermined particle diameter range, which have stayed within said reaction chamber, onto the substrate by taking advantage of the post-reaction gas flow.

According to another aspect of the present invention, there is provided a particle deposition apparatus for allowing a starting gas to react to produce particles which are then deposited onto a substrate, said apparatus comprising: a reaction vessel comprising a reaction chamber and a back chamber defined in its interior, a starting gas supply port in communication with said reaction chamber, an exhaust port in communication with said back chamber, a holder which is disposed within said back chamber and can hold said substrate, and particle blocking unit provided so as to be disposed between said reaction chamber and said substrate; and a plasma generator for producing plasma within said reaction chamber.

According to a further aspect of the present invention, there is provided a particle deposition method for allowing a starting gas to react to produce particles and agglomerates of the particles which are then deposited onto a substrate, said method comprising the steps of: generating plasma within a reaction chamber while supplying said starting gas into the reaction chamber and exhausting gas from a back chamber located on the downstream of the reaction chamber to grow said particles as a reaction product of the starting gas within the plasma; and blocking the agglomerates of the particles by particle blocking unit.

The present invention can provide a particle deposition apparatus and particle deposition method that can form a particle deposited layer of particles having a predetermined uniform particle diameter in a relatively small number of steps.

### BRIEF DESCRIPTION OF THE DRAWINGS

FIG. 1 is a schematic diagram of a particle deposition apparatus in a first embodiment of the present invention;

FIG. 2 is a graph showing an example of a particle diameter distribution in a particle deposited layer formed by a method in a first embodiment of the present invention; and

FIG. 3 is a schematic diagram of a particle deposition apparatus in a second embodiment of the present invention.

### DETAILED DESCRIPTION OF THE INVENTION

Embodiments of the present invention will be described with reference to the accompanying drawings. The same or like elements are identified with the same reference characters, and the overlapped explanation thereof will be omitted.

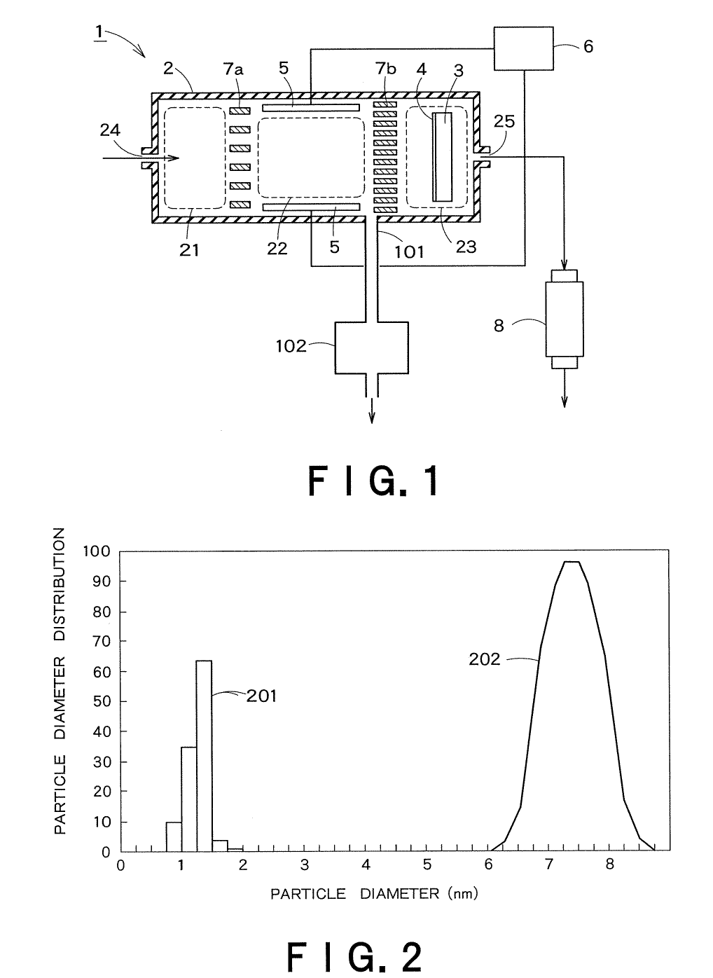

FIG. 1 is a schematic diagram of a particle deposition apparatus in a first embodiment of the present invention. This particle deposition apparatus 1 comprises a reaction vessel 2. The reaction vessel 2 is, for example, in a tubular form. A front chamber 21, a reaction chamber 22, and a back chamber 23 are defined within the reaction vessel 2. A starting gas supply port 24 in communication with the front chamber 21 is provided at one end of the reaction vessel 2. A starting gas is supplied through the starting gas supply port 24 into the front chamber 21. An exhaust port 25 in communication with the back chamber 23 is provided at the other end of the reaction vessel 2. Gas is exhausted throught the exhaust port 25. The exhaust gas discharged through the exhaust port 25 is cooled with a cooler 8. A particle discharge port 101 is provided in the reaction vessel 2, and particles outside a desired particle diameter range are discharged through the particle discharge port 101.

A holder 3 is provided within the back chamber 23 in the reaction vessel 2. The holder 3 holds a substrate 4 detachably in such a state that faces the reaction chamber 22. Further, a plasma generator 5 for generating plasma within the reaction chamber 22 is provided in the reaction vessel 2.

A particle discharge port 101 is provided in the reaction vessel 2, and unit 102 for regulating gas flow is provided so as to discharge particles through the particle discharge port 101.

The plasma generator 5 is connected to a control unit 6. The control unit 6 controls the operation of the plasma generator 5. Specifically, the control unit 6 can control the operation of the plasma generator 5 so that alternate switching between the generation and disappearance of plasma is repeatedly carried out at a very high speed, for example, on the order of milliseconds.

In the reaction vessel 2, a distributor 7a is provided between the front chamber 21 and the reaction chamber 22, and a distributor 7b is provided between the reaction chamber 22 and the back chamber 23. The distributors 7a and 7b can prevent the occurrence of turbulent flow in the reaction chamber 22 and the back chamber 23 and further can suppress a variation in flow rate in the cross-sectional direction.

When the distributors 7a and 7b are provided, the distributor 7a can also be used as a plasma generator by connecting the distributor 7a to the control unit 6. According to this construction, the volume of the reaction vessel 2 can be effectively used.

A heater (not shown) for heating the atmosphere within the reaction chamber 22 may also be provided in the reaction vessel 2. The provision of the heater can promote a plasma decomposition reaction which will be described later.

When this particle deposition apparatus 1 is used, a particle deposited layer may be formed, for example, by the following method. Here, in the formation of a particle deposited layer, FePt particles utilizable, for example, as a magnetic medium are used as the particles to be deposited as an example.

At the outset, in such a state that the particle discharge port 101 is open, a carrier gas stored in a carrier gas tank (not shown) is supplied through the gas supply port 24 into the front chamber 21 in the reaction vessel 2. A stream of gas, which flows from the gas supply port 24, is passed through the front chamber 21, the reaction chamber 22, and the particle discharge port 101 and flows into the outside of the reaction chamber, is produced by the gas flow control unit 102. For example, argon, helium, xenon, nitrogen, and hydrogen may be used as the carrier gas.

Next, a starting gas stored in a starting gas tank (not shown) is supplied through the starting gas supply port 24 into the front chamber 21 in the reaction vessel 2. In this case, for example, the pressure within the reaction vessel 2 is brought to not more than 1 torr, and the temperature of the starting gas is set to approximately room temperature. Here, for example, a starting gas comprising (C₅H₅)₂Fe (ferrocene) and CH₃C₅H₄(CH₃)₃Pt ((methylcyclopentadienyl) trimethylplatinum) may be used.

Substantially simultaneously with the supply of the starting gas, the plasma generator 5 is operated to generate plasma within the reaction chamber 22.

Upon the generation of plasma within the reaction chamber 22, for example, a decomposition reaction represented by the following reaction formula takes place in a region excited by plasma discharge (hereinafter referred to as “reaction region”).

Iron material→Iron atom+produced gas

Platinum material→platinum atom+produced gas

An iron atom and a platinum atom as materials for particles and gases as a decomposition by-product are produced by the above reaction. The gases produced as the by-product are exhausted as the post-reaction gas together with the carrier gas through the particle discharge port 101.

The iron and platinum atoms thus produced are moved within the reaction chamber and collide with each other to form FePt particles. Since a gas stream of the starting gas and the post-reaction gas is formed within the reaction vessel 2, for example, by the carrier gas, the particles produced within the reaction chamber 22 undergo physical drag directed from the front chamber 21 side to the back chamber 23 side. On the other hand, the particles present within the reaction chamber 22 are instantaneously negatively charged within the plasma discharge space. Accordingly, Coulomb force acts on the produced particles by the electric field applied for generating plasma, and the particles stay within the reaction chamber 22. Specifically, drag from the gas stream and the electric field-derived Coulomb force act on the formed FePt particles. When the particles have a suitable particle diameter, due to the action of large Coulomb force, the particles are trapped within the reaction region. A part of the trapped particles are then rendered neutral in a sheath region in the electric field of the plasma only for a very short period of time in the plasma period (73 nsec in conventional RF plasma). In this case, the particles collide and coalesce with each other and consequently are grown to larger particles. When the growth proceeds, agglomerates are formed.

As described above, the Coulomb force and the drag act on the particles present in the reaction chamber 22. Since the electrification amount of the particles is proportional to the particle diameter, the electrification amount of particles having a very small particle diameter is small, and, thus, the level of the action of the Coulomb force is small. Accordingly, in this case, the level of the action of the drag is large, and, thus, these particles are pushed out to the outside of the reaction chamber. On the other hand, since the drag which the particles undergo is proportional to the square of the particle diameter, a high level of drag acts on particles having a very large particle diameter, and, thus, these particles are also pushed out to the outside of the reaction chamber. Thus, due to the action of the Coulomb force and the drag, particles having an excessively small particle diameter and particles having an excessively large particle diameter among the particles produced by the plasma are always taken out of the reaction region. On the other hand, particles having a suitable particle diameter are continuously trapped within the reaction chamber. Consequently, the density of the particles having a suitable particle diameter within the reaction chamber is increased.

After the particle formation reaction by discharge for a predetermined period of time, the particle discharge port 101 is closed, and a gas stream, which is passed through the back chamber 23 and the exhaust port 25 and reaches a cooler 8, is produced. Upon the disappearance of plasma discharge substantially simultaneously with this, the Coulomb force, which acts to hold the particles within the reaction chamber 22, disappears. As a result, due to the drag attributable to the gas stream formed by the carrier gas, the FePt particles present within the reaction chamber 22 are moved downward and are deposited onto a substrate 4. At that time, particles moved from the reaction chamber toward the substrate are in an electrified state until they are deposited onto the substrate 4. Accordingly, the particles are repulsive to each other until deposition onto the substrate 4 and thus are deposited evenly on the substrate.

According to the above method, only particles having suitable particle diameters produced by the plasma can be deposited onto the substrate 4, and, thus, a variation in diameter of particles deposited on the substrate can be suppressed. The diameter of the particles to be deposited onto the substrate may be properly selected according to the application of the substrate to be produced. Preferably, however, the particle diameter is 1 to 2 nm, for example, from the viewpoint of the quantum effect of the particles. The diameter of the particles deposited onto the substrate may be regulated by properly setting, for example, the pressure within the reaction chamber, the flow rate of the carrier gas, and the electric power applied by the plasma generator. For example, in the above embodiment of the production of FePt particles, a method may be adopted in which particles having a diameter of about 1 nm are formed under conditions of pressure within reaction chamber 0.2 to 0.4 torr, carrier gas flow rate 20 to 40 cm/sec, and plasma power 50 to 100 W and are deposited onto a substrate.

FIG. 2 is a graph showing an example of a particle diameter distribution in a particle deposited layer formed by a method in a first embodiment of the present invention. In the drawing, a curve 201 represents data in a particle diameter distribution of particles produced by plasma and deposited onto a substrate. A curve 202 represents data of a particle diameter distribution of agglomerates produced by plasma. In this example, it is apparent that particles of 1 to 2 nm are deposited onto the substrate, and large particles having a diameter of more than 6 nm are produced in the reaction region. Particles having a diameter between 6 nm and 2 nm are not observed. The reason for this is believed to reside in that, since particles agglomerated in the reaction chamber have an increased sectional area, the frequency of collision thereof with other particles is increased and, thus, once agglomerated particles are immediately coarsened. Accordingly, the particle diameter distribution is bipolarized, and, thus, in the present invention, particles having a proper particle diameter can be selectively deposited onto the substrate.

As described above, in this embodiment, since particles having a relatively uniform particle diameter can be produced within the reaction chamber 22, particles classification is unnecessary. Therefore, particle collection for classification is not necessary, and, as shown in FIG. 1, particles produced within the reaction chamber 22 can be deposited directly on the substrate 4 disposed within the back chamber 23. Accordingly, the preparation of a dispersion liquid of classified particles and coating of the dispersion liquid are also unnecessary. That is, in this embodiment, a particle deposited layer of particles having a uniform particle diameter can be formed in a relatively small number of steps, and, thus, the cost involved in the particle deposited layer formation can be reduced.

Next, the second embodiment of the present invention will be described.

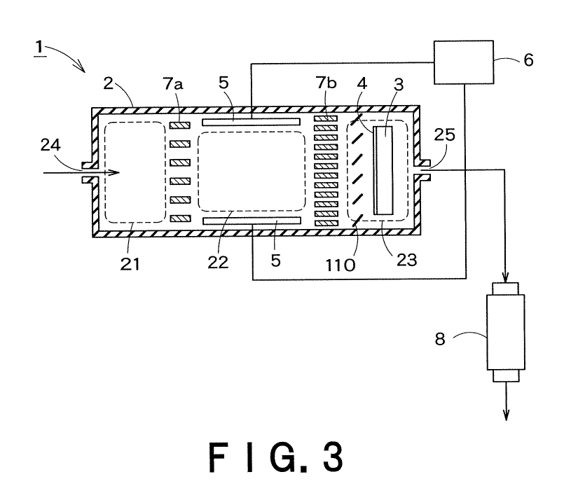

FIG. 3 is a schematic diagram of a particle deposition apparatus in a second embodiment of the present invention. The particle deposition apparatus shown in FIG. 3 has the same construction as the particle deposition apparatus 1 shown in FIG. 1, except that the apparatus shown in FIG. 3 is not provided with any particle discharge port but provided with a particle blocking plate 110 as particle blocking unit.

The particle blocking plate 110 comprises turn control unit (not shown). Specifically, when the particle blocking plate 110 is turned along an axis perpendicular to the drawing to become parallel to the substrate, the plate is closed and covers the substrate surface. As a result, the gas flow from the reaction chamber 22 takes a roundabout route and is led to the discharge port 25 without passage onto the substrate surface. On the other hand, when the particle blocking plate 110 is turned to a position perpendicular to the substrate, that is, an open state, the gas flow from the reaction chamber 22 is led to the substrate surface and, consequently, the particles contained in the carrier gas are deposited onto the substrate.

When this particle deposition apparatus 2 is used, a particle deposited layer may be formed, for example, by the following method. Here, in the formation of a particle deposited layer, FePt particles are used as the particles to be deposited as an example.

At the outset, after closing the particle blocking plate 110, a carrier gas stored in a carrier gas tank (not shown) is supplied through the gas supply port 24 into the front chamber 21 in the reaction vessel 2. A stream of gas, which flows from the gas supply port 24, is passed through the front chamber 21, the reaction chamber 22, the back chamber 23, and the discharge port 25 and reaches a cooler 8, is produced. For example, argon, helium, xenon, nitrogen, and hydrogen may be used as the carrier gas.

Next, a starting gas stored in a starting gas tank (not shown) is supplied through the starting gas supply port 24 into the front chamber 21 in the reaction vessel 2. In this case, for example, the pressure within the reaction vessel 2 is brought to 1 torr, and the temperature of the starting gas is set to approximately room temperature. Here, for example, a starting gas comprising (C₅H₅)₂Fe (ferrocene) and CH₃C₅H₄(CH₃)₃Pt ((methylcyclopentadienyl) trimethylplatinum) may be used.

Substantially simultaneously with the supply of the starting gas, the plasma generator 5 is operated to generate plasma within the reaction chamber 22. In this case, the particle blocking plate 110 is allowed to remain closed.

Upon the generation of plasma within the reaction chamber 22, for example, a decomposition reaction represented by the following reaction formula takes place in a region excited by plasma discharge (hereinafter referred to as “reaction region”).

Iron material→Iron atom+produced gas

Platinum material→platinum atom+produced gas

An iron atom and a platinum atom as materials for particles and gases as a decomposition by-product are produced by the above reaction. The gases produced as the by-product are exhausted together with the carrier gas through the exhaust port 25 and are cooled in a cooler 8.

The produced iron and platinum atoms collide with each other to form FePt particles, and particles having a proper particle diameter are trapped within the reaction chamber 22 through the same mechanism as described above.

After the production of particles of by plasma discharge for a predetermined period of time, the particle blocking plate 110 is opened, and, substantially simultaneously with this time, plasma discharge is allowed to disappear, whereby FePt particles having a small particle diameter produced within the reaction chamber 22 are moved toward the downstream side by the gas stream produced by the carrier gas. The FePt particles having a small particle diameter produced within the reaction chamber 22 and moved toward the downstream side by the gas stream produced by the carrier gas are deposited onto the substrate 4.

In the first and second embodiments described above, FePt particles have been produced by using a starting gas containing an iron-containing compound and a platinum-containing compound. However, it should be noted that the composition of the particles produced in the present invention is not limited to FePt. Specifically, various starting gases may be used. For example, the starting gas may comprise a compound containing iron, a compound containing platinum, or a compound containing iron and platinum, and a compound containing at least one element selected from the group consisting of copper, silver, tin, antimony, lead, gallium, mercury, molybdenum, and tungsten. Alternatively, the starting gas may comprise a compound containing gallium, a compound containing aluminum, a compound containing indium, a compound containing cadmium, a compound containing mercury, a compound containing zinc, or a compound containing gallium and nitrogen, and a compound containing at least one element selected from the group consisting of arsenic, phosphorus, selenium, copper, silver, tin, antimony, lead, and silicon. Further, in the first and second embodiments, particles have been produced by reacting decomposition products of a plurality of kinds of compounds with each other. Alternatively, particles may be produced from a decomposition product of one compound.

In the first and second embodiments, prior to the step of particle growth and the step of particle deposition, the substrate may be electrified. In the step of particle deposition, particles supplied from the reaction chamber may be subjected to mass separation followed by deposition onto the substrate.

In the first and second embodiments, a construction may be adopted in which at least one of distributors 7a and 7b is formed of an electroconductive material and voltage is added thereto. For example, in growing the particles, the movement of the particles from the reaction chamber 22 to the back chamber 23 can be suppressed, for example, by applying voltage having the same polarity as the electrification polarity of the particles to the distributor 7b. In the deposition of the particles onto the substrate 4, for example, the movement of the particles from the reaction chamber 22 to the back chamber 23 can be promoted, for example, by applying voltage having the same polarity as the electrification polarity of the particles to the distributor 7a.

In the first and second embodiments, in producing particles within the reaction chamber 22, an etching gas for etching the particle surface may be supplied together with the starting gas, carrier gas or the like, into the reaction chamber 22. In this case, growth of the particles and agglomerates to an excessively large diameter can be suppressed.

Further, in the first and second embodiments, a construction may be adopted in which a window part is provided in the reaction vessel 2 and a light source such as an ultraviolet lamp is disposed outside the reaction vessel. In this case, light from the light source may be applied to the starting gas to excite the starting gas and thus to promote the chemical reaction.

In the first and second embodiments, the particle production/growth and the deposition of the particles onto the substrate can be repeatedly carried out. The above procedure can increase the amount of the particles deposited onto the substrate.

The present invention is not limited to the above embodiments, and various modifications are possible without departing from the subject matter of the present invention. For example, regarding blocking of the particles, the orientation of the substrate per se may be turned by 180 degrees to a gas stream containing particles and agglomerates to block the particles and agglomerates from the substrate. It is also possible to block the particles and agglomerates by allowing a purge gas to flow from around the substrate countercurrently against the gas stream containing particles and agglomerates.

The present invention provides a particle deposition apparatus and a particle deposition method that can form a particle deposited layer of particles having a uniform particle diameter in a relatively small number of steps. A substrate with particles deposited thereon produced by the apparatus or method can be advantageously utilized, for example, in magnetic recording media, because particles having a uniform particle diameter are evenly deposited. In particular, such substrates can be utilized in advanced magnetic recording media, in which information is recorded on each particle, expected in the future.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A particle deposition apparatus for reacting starting materials in a starting gas with each other to produce particles which are then deposited onto a substrate, said apparatus comprising:
a reaction vessel comprising a reaction chamber and a back chamber, a starting gas supply port in communication with said reaction chamber, an exhaust port in communication with said back chamber, and a holder which is disposed within said back chamber and can hold said substrate;
a plasma generator for producing plasma within said reaction chamber; and
gas flow control unit configured to discharge a post-reaction gas through said exhaust port while producing said plasma.

2. The particle deposition apparatus according to claim 1, which further comprises a particle discharge port connected to said back chamber, for discharging particles outside a predetermined particle diameter range and said post-reaction gas.

3. The particle deposition apparatus according to claim 1, which further comprises particle blocking unit provided so as to be disposed between said reaction chamber and said substrate.

4. The particle deposition apparatus according to claim 1, which further comprises a distributor on the upstream or downstream of said reaction chamber.

5. The particle deposition apparatus according to claim 1, wherein said distributor is formed of an electroconductive material and the movement of said particles is regulated by applying voltage to said distributor.

6. The particle deposition apparatus according to claim 1, which further comprises a heater for heating an atmosphere in said reaction chamber.

7. The particle deposition apparatus according to claim 1, wherein said reaction vessel comprises a window part, and a light source for promoting a chemical reaction within the reaction vessel is provided on the outside of said reaction vessel.

8. A particle deposition method for reacting starting materials in a starting gas with each other to produce particles which are then deposited onto a substrate, said method comprising the steps of:
(1) generating plasma while supplying said starting gas into a reaction chamber capable of generating plasma, whereby particles are produced and are grown within said reaction chamber and particles having a diameter falling within a predetermined range are allowed to stay within said reaction chamber;
(2) discharging a post-reaction gas and particles larger than the upper limit of a predetermined particle diameter range, separated within said reaction chamber, from said reaction chamber; and
(3) allowing said plasma to disappear to deposit particles falling within a predetermined particle diameter range, which have stayed within said reaction chamber, onto the substrate by taking advantage of the post-reaction gas flow.

9. The method according to claim 8, wherein said steps (1) to (3) are repeated.

10. The method according to claim 8, wherein the diameter of the particles deposited on said substrate is 1 to 2 nm.

11. The method according to claim 8, wherein said starting gas comprises a compound containing iron, a compound containing platinum, or a compound containing iron and platinum, and a compound containing at least one element selected from the group consisting of copper, silver, tin, antimony, lead, gallium, mercury, molybdenum, and tungsten.

12. The method according to claim 8, wherein said starting gas comprises a compound containing gallium, a compound containing aluminum, a compound containing indium, a compound containing cadmium, a compound containing mercury, a compound containing zinc, or a compound containing gallium and nitrogen, and a compound containing at least one element selected from the group consisting of arsenic, phosphorus, selenium, copper, silver, tin, antimony, lead, and silicon.

13. The method according to claim 8, wherein said substrate has been previously electrified.

14. The method according to claim 8, wherein a carrier gas, together with said starting gas, is supplied into said reaction chamber.

15. The method according to claim 8, wherein an etching gas, together with said starting gas, is supplied into said reaction chamber.
